(19) United States
(12) Patent Application Publication
(10) Pub. No.: US 2005/0161744 A1
(43) Pub. Date: Jul. 28, 2005

(54) Radiation hardened MOS structure

(75) Inventors: Ivan Frapreau, Fondettes (FR); Crispino S. Abella, S. Agata Li Battiati (CT) (IT); Alfio Mazza, Catania (IT)

Correspondence Address: JENKENS & GILCHRIST, PC, 1445 ROSS AVENUE, SUITE 3200, DALLAS, TX, 75202, US

(73) Assignees: STMicroelectronics S.A., Montrouge (FR); STMicroelectronics S.r.I., Agrate Brianza (IT)

(21) Appl. No.: 11/010,642

(22) Filed: Dec. 13, 2004

(30) Foreign Application Priority Data
Dec. 11, 2003 (EP) 03293117.2

(51) Int. Cl. H01L 31/119; H01L 29/76

(52) U.S. Cl. 257/368

(57) ABSTRACT

A radiation hardened MOS structure is integrated on a semiconductor substrate. The structure includes a MOS transistor realized in an active area surrounded by an isolation layer. The MOS transistor includes a channel region delimited by opposed source and drain regions of a first type of conductivity and a gate region formed above the channel and insulated from it by a thin oxide layer. The radiation hardened MOS structure includes a guard ring element of a second type of conductivity, formed in the semiconductor substrate under the isolation layer. The source and drain regions are spaced away from the isolation layer.

### PRIORITY CLAIM

The present application claims priority from European Patent Application No. 03293117.2 filed Dec. 11, 2003, the disclosure of which is hereby incorporated by reference.

### BACKGROUND OF THE INVENTION

1. Technical Field of the Invention

The present invention relates to an integrated circuit technology and, more particularly, to a radiation-hardened circuit technology.

2. Description of Related Art

Semiconductor devices and integrated circuits (ICs) used in outer space, for example, in a satellite, are subjected to severe environmental conditions that may cause electrical parameter drift and/or logic failure.

Every IC used in a space application should remain functional for the lifetime of the satellite, which may be as long as several years.

To complicate this task it must be noted that there are several forms of high-energy particles in outer space. For example, there are alpha particles and gamma rays, just to name a few.

These high-energy particles strike the semiconductor material on which the MOS integrated circuit devices are formed with enough energy to cause the generation of electron-hole pairs.

The resulting charge carriers are often trapped in the various oxide layers of the devices. In the case of metal oxide semiconductor (“MOS”) transistors, charges trapped in the gate oxide will shift the threshold voltage Vt, of the transistor. As a result, leakage currents of the transistors, and consequently, of the IC device will affect performance and system efficiency.

The frequency or number of charges trapped in an oxide layer is proportional to the thickness of the oxide layer. Consequently, oxides having a greater thickness will, on the average, have a greater number of trapped charges. In the case where the oxide is relatively thick, for example, approximately 4000-5000 Å (Angstrom), charge trapped in the oxide will result in a much more dramatic shift in the leakage current characteristics than for an active transistor having a relatively thin gate oxide.

The application of a thick oxide is specific for isolating active transistor areas in which MOS cells may be formed, for example, regions of local oxidation of silicon (“LOCOS”). The accumulating charge trapped in the LOCOS region may become great enough to cause a conduction channel to form below the LOCOS region, and consequently allow current to leak between neighboring active transistor regions.

As previously mentioned, transistors in the active region of a high-speed logic IC device, which typically have gate oxides that are much thinner than the oxides of the LOCOS region, will have a shifting threshold voltage Vt as a result of the trapped charges in the gate oxide.

In order to solve this drawback a prior art solution method has been used to accommodate the shifting threshold voltage Vt by raising the threshold voltage Vt of the active transistors, so that the relative changes in the Vt due to the trapped charges are reduced.

This method is disclosed in the article by Pierre Jarron et al. entitled “Deep submicron CMOS technologies for LHC experiment”—Nuclear Physics B (Proc. Suppl.) 78 (1999) pages 625-634, this disclosure of which is incorporated by reference.

Thus, the effect that trapped charges will have on the overall performance of the IC devices is minimized. However, the mentioned technique is not as effective when applied to LOCOS isolation regions. Although the Vt of the incidental transistor of the LOCOS isolation regions may be adjusted so that the Vt shift due to charge trapped in the thick oxide is relatively small, the resulting isolation region will have an unacceptably low breakdown voltage.

Another known technique used to accommodate charges trapped in a thick LOCOS isolation region is that of creating a two-layer oxide isolation structure.

A relatively thin layer of oxide of approximately 500 Å is grown in the isolation region, followed by the formation of a relatively thick layer of phosphorous doped oxide of approximately 4000 Å over the relatively thin layer of oxide. The phosphorous doped oxide is subsequently densification process step by baking.

The resulting structure minimizes the effect trapped positive charges have on the leakage characteristics of the isolation region by neutralizing the trapped positive charges with the abundance of electrons of the relatively thick phosphorous doped oxide. However, this approach is limited by the doping concentration of the relatively thick oxide layer. That is, the greater the level of impurities, the greater the diffusion of the impurities from the thick oxide into the adjacent layers.

It should be noted that the part of a MOS structure most sensitive to ionizing radiation is the oxide insulating layer.

When the radiation passes through the oxide, the energy deposited creates electron/hole pairs. The radiation-generated electrons are more mobile than the holes and are swept out of the oxide in about a picosecond. During this moment, a fraction of the electrons and holes recombine. The amount of recombination depends on the applied field and the kind and energy of the incident particle.

The holes that escape the initial recombination are relatively immobile and remain near their point of generation, thereby causing negative voltage shifts in the electrical characteristics of the MOS device. But over a longer period of time, exceeding one second, the holes undergo a rather anomalous stochastic hopping transport through the oxide in response to any electric fields present.

This hole transport process gives rise to a short-term, transient recovery in the voltage shift. When the holes reach the SiO₂ interface (for positive gate bias), some of them are captured in long-term trapping sites, and cause a remnant negative voltage shift that is not sensitive to the silicon surface potential, which can last from hours to years.

This long-term radiation-induced voltage shift is a common form of radiation damage in MOS devices. The long-term trapping of holes (i.e., a net positive charge in the oxide layer) near the interface, as well as subsequent annealing of them, is sensitive to the processing of the oxide and to field and temperature. This effect generally dominates other radiation damage processes in MOS structures.

Much effort in the related art has been directed toward reducing and controlling oxide positive charge trapping. Early radiation-insensitive MOS circuits had ionic contaminants in the gate oxide materials to alter and improve the oxide properties under radiation.

Later on, MOS device fabrication techniques and process controls in the related art improved, and thus the hardening techniques that relied on impurity addition to the oxide fell out of favor (at least for gate oxide). Radiation hardening then concentrated on the primary source of the radiation-generated oxide positive charge (i.e., the trapped hole). A hole trap designates normally neutral oxide defects that can capture holes and retain then for long periods of time.

Radiation-induced generation and trapping of holes is a problem in both gate oxide and field or silicon oxide of MOS devices. Field oxides are typically about an order of magnitude thicker than gate oxides. The properties of field oxides are not as well controlled as those of gate oxides.

In the related art, field oxides may be produced by processes such as chemical vapor deposition (CVD), not used for gate oxides. Threshold voltage changes due to radiation are proportional to the square of the oxide thickness. For instances a relatively small radiation dose causes a significant change in threshold voltage in a parasitic field oxide field effect transistor (FET).

A solution of this kind is disclosed for instance in the U.S. Pat. No. 6,063,690 to Woodruff et al. entitled “Method for making recessed field oxide for radiation hardened microelectronics”, the disclosure of which is incorporated by reference.

Greater oxide thickness also results in smaller electric fields in the oxides. Smaller fields reduce charge yield and enhance both hole capture and electron/hole recombination at the hole traps. Greater oxide thickness also increases the charge-generation volume and the distance that both holes and electrons must travel to escape the oxide, which in turn enhances trapping and recombination. The net result is that space and recombination effects begin to dominate the voltage threshold change of field oxides at doses of a few Krad (SiO₂), two or three orders of magnitude below the levels of radiation that typically cause such effects in the thinner gate oxides.

Both the increase in oxide thickness and the decrease in the oxide field also greatly increase the time scale of hole transport through the oxide. Hence, substantial hole transport may take place in a field oxide for thousands of seconds after being subject to radiation.

Another way to eliminate leakage due to the bird beak effect uses some innovative MOS layouts (see, for example, FIG. 1) that can avoid the undesired leakage path. This study that considers true ring MOS was conducted by CERN at Geneva, it works but is not good for design in terms of occupied area and true W/L calculation.

There is accordingly a need to provide a radiation hardened CMOS structure having structural and functional features allowing to control the leakage currents due to isolation region, increasing the lifetime of the device even under extreme or severe environmental working conditions.

In particular, there is a need to provide a radiation hardened CMOS structure which controls both the leakage current localized just under isolating region (LOCOS), named inter-transistor leakages, and leakage current on the boarder of the active area all around the transistor, named intra-transistor leakages.

### SUMMARY OF THE INVENTION

Embodiments of the present invention solve the foregoing and other problems by providing a radiation hardened CMOS structure which comprises a MOS transistor having a guard ring element all around each MOS transistor and the bird beak regions all around the transistor are pushed away from the active area of the MOS transistor.

In accordance with an embodiment of the present invention, a radiation hardened MOS structure is integrated on a semiconductor substrate and comprises a MOS transistor formed in an active area and surrounded by an isolation layer. The MOS transistor comprises:
a channel region delimited by opposed source and drain regions; and
a gate region formed above the channel region and insulated from the channel region by a thin oxide layer.
   The radiation hardened MOS structure comprises:
a guard ring element, formed in the semiconductor substrate under the isolation layer, wherein the source and drain regions of the MOS transistor are spaced away from the isolation layer.

The features and advantages of the device according to embodiments of the invention will be apparent from the following detailed description, given as non-limiting examples with reference to the accompanying drawings.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 is a schematic top view showing a comparison between a standard MOS structure and an edgeless MOS structure;

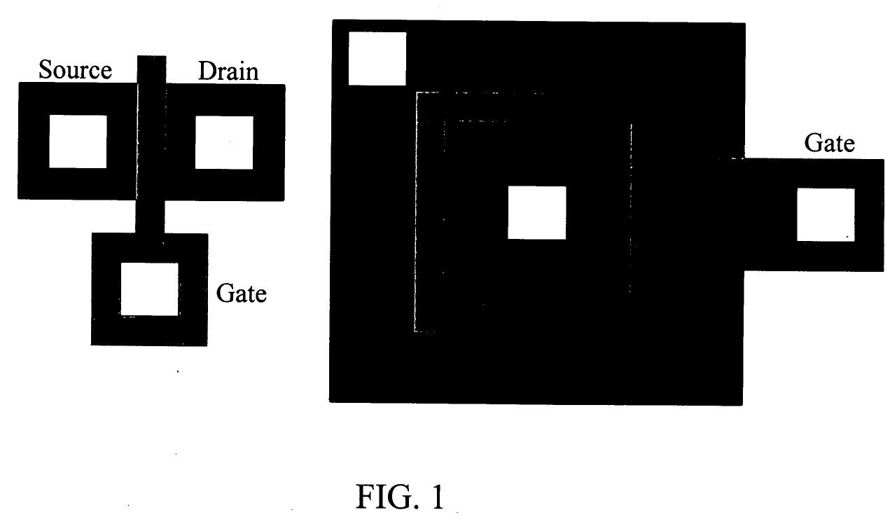

FIG. 2 is an enlarged scale and schematic top plan view of a NMOS structure obtained according to the method of the present invention;

FIG. 3 is an enlarged scale and schematic cross sectional view of the NMOS structure of FIG. 2;

FIG. 4 is an enlarged scale and schematic top plan view of an PMOS structure obtained according to the method of the present invention; and

FIG. 5 is an enlarged scale and schematic cross sectional view of the PMOS structure of FIG. 4.

### DETAILED DESCRIPTION

Embodiments of the invention relate particularly, but not exclusively, to a radiation hardened MOS structure integrated on a semiconductor substrate and the following description is made with reference to this field of application for convenience of illustration only.

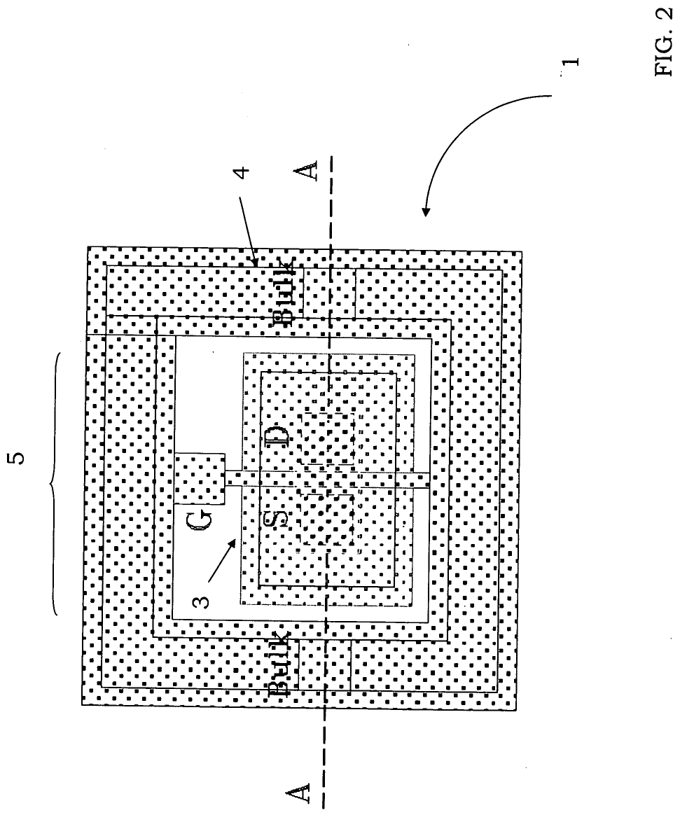

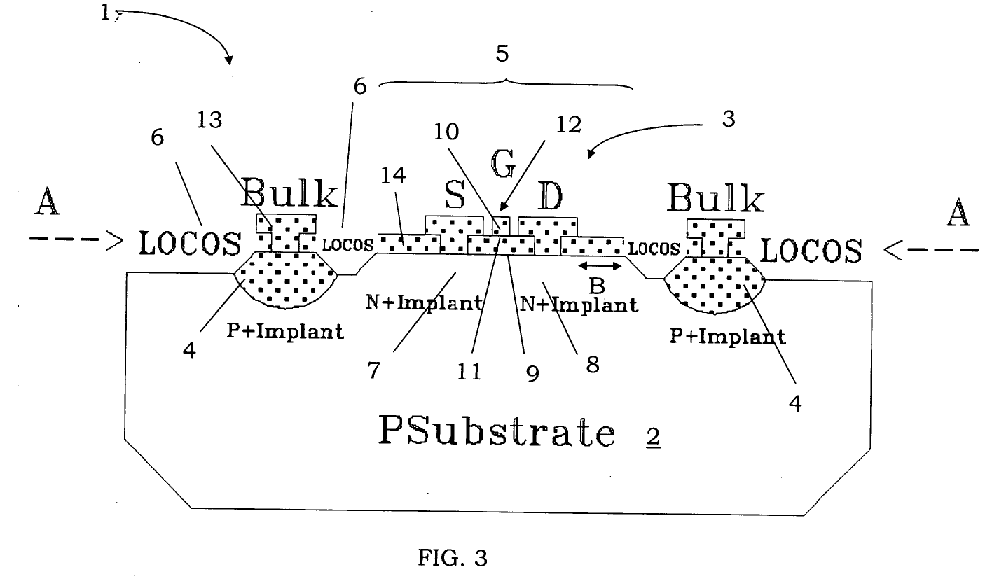

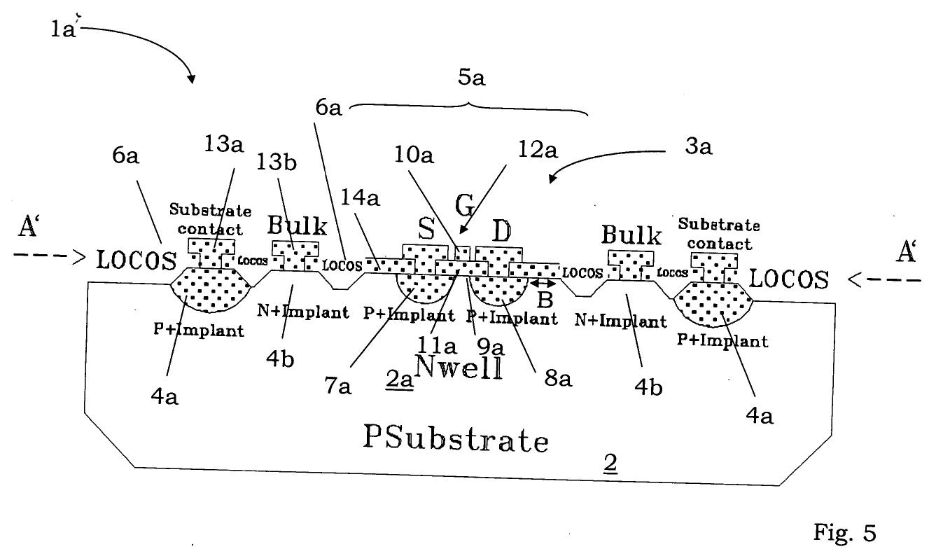

With reference to FIGS. 2 to 5, a radiation hardened MOS structure is described. In these FIGURES the cross-sections shown through a semiconductor wafer are not drawn to scale but rather to highlight major features of the invention.

According to an aspect of the invention, the radiation hardened MOS structure 1, integrated on a semiconductor substrate 2, comprises NMOS transistor 3 and a guard ring element 4 surrounding the NMOS transistor 3.

The NMOS transistor 3 is formed in active area 5 surrounded by a thick isolation layer 6, for example a thick oxide layer of LOCOS type.

The NMOS transistor 3 comprises a drain region 7 and a source region 8, formed by an N-type implant in the semiconductor substrate 2.

The substrate region included between the drain 7 and source 8 regions forms a channel region 9 of the NMOS transistor 3. The channel region 9 is overlaid by a gate region 10 in an isolated manner from said channel region and with the interposition of an oxide layer 11. The gate region 10 is conventionally formed by a conductive layer 12, for example polysilicon.

According to an aspect of the invention, the radiation hardened NMOS structure 1 comprises a guard ring element 4 provided outside the active area 5 under the thick oxide layer 6. This guard ring element 4 is formed by an P-type implant in the semiconductor substrate 2.

Advantageously, at least an opening is formed in the thick oxide layer 6 aligned with the guard ring element 4 to realize an electric contact 13.

This guard ring element acts as a stop channel between two NMOS transistors so that no communication is possible between two adjacent NMOS transistors. This first design improvement provides an efficient way to stop inter-transistor leakages.

As far as intra-transistor leakages are concerned, the aim is to avoid an abnormal turn-on of the NMOS transistor submitted to radiation due to accumulated charges at the extreme limit of the bird beak problem.

In particular, the source 7 and drain 8 regions are spaced away from the thick oxide layer 6.

So, the source drain regions 7, 8 are provided at a B distance far from the thick oxide layer 6.

A thin oxide layer 14 is then formed on the semiconductor substrate 2 between the source drain regions 7, 8 and the thick oxide layer 6.

Advantageously, the thin oxide layer 14 is the same as the thin oxide layer 11.

So, bird beak regions all around the transistor, formed between the thick oxide layer 6 and thin oxide layer 14, are pushed away from the active area of the NMOS transistor.

Advantageously, for each MOS technology, a distance B will be optimized in order to reach the target of predetermined total dose that the structure 1 has to withstand.

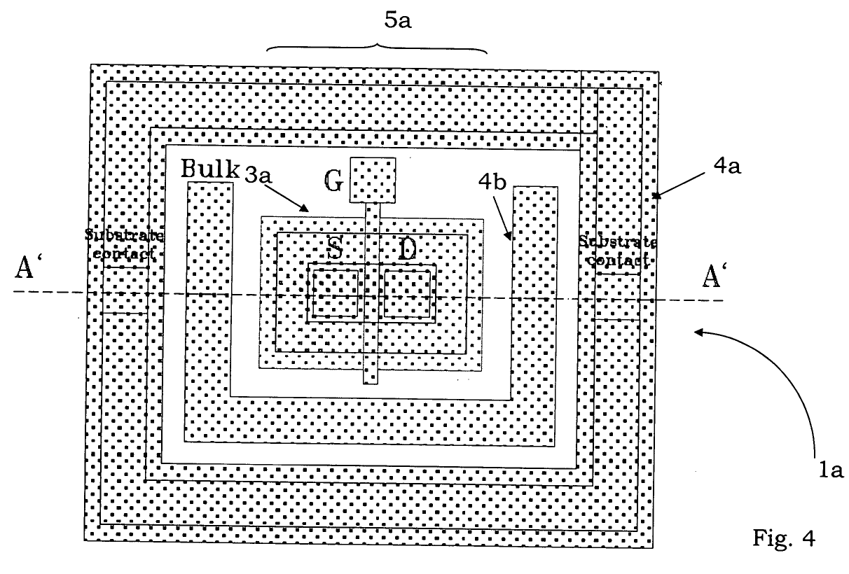

These two solutions related to physical phenomena on radiation behavior of MOS structures that occur on NMOS transistor have also been implemented in PMOS structures in order to have a balanced structure for IC designs, as shown in FIG. 4, 5.

In particular, a radiation hardened PMOS structure 1a, integrated on a semiconductor substrate 2 is described.

An N-well 2a is formed in the semiconductor substrate 2, wherein a PMOS transistor 3a and a guard ring element 4a surrounding the PMOS transistor 3a are formed.

The PMOS transistor 3a is formed in active area 5a surrounded by a thick oxide layer 6a, for example LOCOS.

The PMOS transistor 3a comprises a drain region 7a and a source region 8a, formed by an P-type implant in the N-well 2a.

The substrate region included between the drain 7a and source 8a regions forms a channel region 9a of the PMOS transistor 3a. The channel region 9a is overlaid by a gate region 10a in an isolated manner from said channel region and with the interposition of an oxide layer 11a. The gate region 10a is conventionally formed by a conductive layer 12a, for example polysilicon.

According to an aspect of the invention, the radiation hardened MOS structure 1a comprises a guard ring element 4a provided outside the active area 5a under the thick oxide layer 6a. This guard ring element 4a is formed by an P-type implant in the semiconductor substrate 2.

Advantageously, at least an opening is formed in the thick oxide layer 6a aligned with guard ring element 4a to realize an electric contact 13a.

Also in this embodiment the guard ring element 4a acts as a stop channel between two adjacent transistors.

Advantageously, the source drain regions 7a, 8a are provided at a B distance far from the thick oxide layer 6a.

A thin oxide layer 14a is then formed on the N-well 2a between source drain regions 7a, 8a and the thick oxide layer 6a.

Advantageously, the thin oxide layer 14a is the same as the thin oxide layer 11a.

So bird beak regions all around the transistor are pushed away from the active area of the PMOS transistor.

In a conventional manner, the N-well 2a is almost surrounded by a junction 4b formed under the thick oxide layer 6a. This junction 4b is formed by an N-type implant in the N-well 2a. At least an opening is formed in the thick oxide layer 6a aligned with junction 4b to realize an electric contact 13b to the N-well 2a.

In conclusion, the advantages of structures 1, 1a according to embodiments of the present invention are listed below:
Small MOS areas increase;
No capacitive effects, so, no modification of electrical behavior of a radiation hardened MOS structure 1 compared to a standard one;
Only one more mask level added with respect to standard MOS; and
Radiation hardened lots are processed by using standard process flows and equipments, this ensures an excellent repeatability and behavior under radiation which will not be impacted by process fluctuations.

Although preferred embodiments of the device of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

1. A radiation hardened MOS structure integrated on a semiconductor substrate, comprising:
a MOS transistor formed in an active area and surrounded by an isolation layer, the MOS transistor including a channel region delimited by opposed source and drain regions, and a gate region formed above the channel region and insulated from the channel region by a thin oxide layer; and
a guard ring element, formed in the semiconductor substrate under the isolation layer,
wherein the source and drain regions of the MOS transistor are spaced away from the isolation layer.

2. The radiation hardened MOS structure of claim 1, wherein the guard ring element is electrically connected with an electric contact formed trough the isolation layer.

3. The radiation hardened MOS structure of claim 1, wherein a second thin oxide layer is provided from the isolation layer to the source and drain regions.

4. The radiation hardened MOS structure of claim 3, wherein the second thin oxide layer is the same as the thin oxide layer.

5. The radiation hardened MOS structure of claim 1, wherein the semiconductor substrate comprises an N-well in which the MOS transistor is formed.

6. The radiation hardened MOS structure of claim 5, further comprising a junction formed in the N-well under the isolation layer.

7. The radiation hardened MOS structure of claim 6, wherein the junction almost surrounds the MOS transistor.

8. The radiation hardened MOS structure of claim 1 wherein the MOS transistor is of a first conductivity type and the guard ring element is of a second conductivity type.

9. A radiation hardened MOS structure integrated on a semiconductor substrate, comprising:
a MOS transistor formed in an active area and surrounded by an isolation layer, the MOS transistor comprising a channel region delimited by opposed source and drain regions spaced away from the isolation layer; and a gate region formed above the channel region and insulated from the channel region by a thin oxide layer;
a guard ring element, formed in the semiconductor substrate under the isolation layer,
wherein the guard ring element is electrically connected with an electric contact formed trough the isolation layer.

10. The radiation hardened MOS structure of claim 9, wherein a second thin oxide layer is provided from the isolation layer to the source and drain regions.

11. The radiation hardened MOS structure of claim 10, wherein the second thin oxide layer is the same as the thin oxide layer.

12. The radiation hardened MOS structure of claim 9, wherein the semiconductor substrate comprises an N-well in which the MOS transistor is formed.

13. The radiation hardened MOS structure of claim 12, further comprising a junction formed in the N-well under the isolation layer.

14. The radiation hardened MOS structure of claim 13, wherein the junction almost surrounds the MOS transistor.

15. The radiation hardened MOS structure of claim 9 wherein the MOS transistor is of a first conductivity type and the guard ring element is of a second conductivity type.

16. A radiation hardened MOS structure integrated in a N-well of a semiconductor substrate, comprising:
a MOS transistor formed in an active area of the N-well and surrounded by an isolation layer, and comprising a channel region delimited by opposed source and drain regions and a gate region formed above the channel region and insulated from the channel region by a thin oxide layer, the source and drain regions being spaced away from the isolation layer; and
a guard ring element, formed in the semiconductor substrate under the isolation layer and electrically connected with an electric contact formed through the isolation layer;
wherein a junction is formed in the N-well under the isolation layer.

17. The radiation hardened MOS structure of claim 16, wherein the junction almost surrounds the MOS transistor.

18. The radiation hardened MOS structure of claim 16, wherein a second thin oxide layer is provided from the isolation layer to the source and drain regions.

19. The radiation hardened MOS structure of claim 18, wherein the second thin oxide layer is the same as the thin oxide layer.

20. The radiation hardened MOS structure of claim 16 wherein the MOS transistor is of a first conductivity type and the guard ring element is of a second conductivity type.

21. A radiation hardened MOS structure integrated on a semiconductor substrate, comprising:
a MOS transistor formed in an active area and surrounded by an isolation layer, the MOS transistor comprising a channel region delimited by opposed source and drain regions spaced away from the isolation layer; and a gate region formed above the channel region and insulated from the channel region by a first thin oxide layer; and
a guard ring element, formed in the semiconductor substrate under the isolation layer,
wherein a second thin oxide layer is provided from the isolation layer to the source and drain regions.

22. The radiation hardened MOS structure of claim 21, wherein the guard ring element is electrically connected with an electric contact formed through the isolation layer.

23. The radiation hardened MOS structure of claim 22, wherein the second thin oxide layer is the same as the first thin oxide layer.

24. The radiation hardened MOS structure of claim 21, wherein the semiconductor substrate comprises an N-well within which the MOS transistor is formed.

25. The radiation hardened MOS structure of claim 24, further comprising a junction formed in the N-well under the isolation layer.

26. The radiation hardened MOS structure of claim 25, wherein the junction almost surrounds the MOS transistor.

27. The radiation hardened MOS structure of claim 21 wherein the MOS transistor is of a first conductivity type and the guard ring element is of a second conductivity type.
